(19) United States
(12) Patent Application Publication
(10) Pub. No.: US 2008/0294951 A1
(43) Pub. Date: Nov. 27, 2008

(54) Methods and devices for testing computer memory

(76) Inventors: Mustafa S. Ahmad, San Jose, CA (US); Robert N. Seymour, Sunnyvale, CA (US)

Correspondence Address: HEWLETT-PACKARD COMPANY;Intellectual Property Administration, P.O. Box 272400, Fort Collins, CO, 80527-2400, US

(21) Appl. No.: 11/797,146

(22) Filed: May 1, 2007

(51) Int. Cl. G11C 29/04

(52) U.S. Cl. 714/719

(57) ABSTRACT

A method, and a corresponding device, provides for testing computer memory having a number of memory elements. The method includes the steps of initializing each memory element to zero, using a seeded random number generator, determining a random address that corresponds to a start point in the memory range, using the seeded random number generator, writing a random data value to the random address, repeating the two previous steps until all memory elements have been written to with random data values, conducting a refresh test of the memory range, and using the same seeded random number generator and the same written random data values, reading each of the memory elements in the memory range.

### BACKGROUND

Memory devices may undergo some type of post-production testing to verify suitability for distribution and sale to customers. Existing test regimes typically employ three distinct tests: random address access, random data generation, and data refresh tests. Each of these tests target a specific aspects of memory operation, but each test comes with costs in terms of overhead.

Current random address tests that access all memory addresses within a memory range could require a significantly long execution time. The inefficiency of the test is attributed to thrashing where a random address could be generated more than once while the test algorithm tries to access all memory locations randomly. In a testing environment, the additional test time needed to access all memory locations is not an ideal solution. If the random access test were instead designed to test only a portion of the memory range, in order to reduce test execution time, there would not be complete assurance that the memory device was defect free.

In order to validate a software mismatch has not occurred (i.e., where a value read back from a memory address does not match what was written to the memory address), current random data tests keep track of the random data that was written to each memory address. The current methods for tracking data, such as storing the random data values to a data structure, are inefficient, and require extra circuitry and components. Writing data to a separate data structure dramatically affects the performance of the test algorithm.

For a refresh test, the memory to be tested may be allocated as a large order of pages or just one single page of memory. As memory is further fragmented, testing allocated memory of a lower order increases the test algorithm's execution time considerably. For example, in a machine where 16 MB of memory is to be tested, the memory may only allocated one megabyte at a time. This fragmented allocation could cause the algorithm's idle time to significantly affect the execution of the algorithm.

### DESCRIPTION OF THE DRAWINGS

The detailed description will refer to the following drawings in which like numerals refer to like items, and in which:

FIG. 1 is an embodiment of a system for post-production testing of a memory module;

FIGS. 2-4(b) are flowcharts illustrating exemplary operations of an embodiment of a memory test algorithm.

### DETAILED DESCRIPTION

A Random Address/Random Data/Refresh Hybrid algorithm, hereafter known as randadref, combines three memory test algorithms (each targeting different memory failure types) into one hybrid algorithm for both efficiency and effectiveness. The first type of algorithm randadref incorporates is a random address test where random addresses are accessed for reads and writes. In a real life scenario, where a host operating system (OS) and/or application is running, memory accessing is not sequential. In fact, memory accessing can be described as random since many memory transactions are being executed in parallel by various processes. This scenario is not addressed by sequential memory testing, which accesses memory in repeatable low address to high address transitions. A random memory accessing environment can be better simulated by a memory algorithm which performs random address accessing. This allows the types of memory failures produced only during real life scenarios to be better produced with an algorithm in a memory testing environment.

The second type of algorithm incorporated is a random data test where random data is generated for reads and writes. Much like random memory accessing, data that is written to memory locations during real life scenarios are more or less random. A host OS and/or application would constantly be reading and writing various data during normal operation. Memory test algorithms that use a static set of patterns do not properly simulate this real life scenario resulting in loss of coverage. Therefore, being able to read and write different random patterns for each address in a memory range is preferred.

The third type of algorithm incorporated is a refresh test where delays are issued before reading data back from memory that was previously written with data. For example, Dual Inline Memory Modules (DIMMs) store data internally but require their contents to be continually refreshed with electrical charges. A refresh algorithm tests the refreshing circuitry of a DIMM by writing data to memory locations, letting the DIMM idle for a specified amount of time, and reading back the contents of the memory locations. The idling during the algorithm's execution causes memory DIMMs to refresh continuously while validating whether data was corrupted during the DIMM refresh cycles. For a refresh test, an operating system kernel may be used to determine memory allocation. The memory allocated by the kernel may be a large order of pages or just one single page of memory. As memory is further fragmented in a system, testing allocated memory of a lower order could increase the algorithm's execution time considerably.

The randadref algorithm incorporates all three of these algorithms for maximizing memory test coverage while minimizing each individual algorithm's limitations and bottlenecks. The randadref algorithm's design results in a single, powerful algorithm aimed at lowering manufacturing costs by reducing both memory test time and warranty costs associated with defective memory devices, such as DIMMs entering the marketplace.

To account for the limitations of random address testing, the randadref algorithm keeps track of the first address within a memory range that has not yet been written to using a pointer known as a base address pointer. The randadref algorithm “knows” an address has not been written to because the randadref algorithm initially writes zeros to the entire memory range and reads the data values back during initialization. As random memory addresses are accessed for writing data to, if the data value at the targeted random address is not zero (meaning the address has already been written to) the base address is incremented until the pointer points to a free address that has a data value of zero (meaning the address has not yet been written to). The same design is used when the randadref algorithm is reading memory addresses back to check for data corruption, except that the data values are all ones instead of zero.

A random number generator is used to produce random numbers to create both the random addresses within an address range, after masking the random numbers, and the random data values to write to the addresses. The random number generator is initially seeded with a value. The random number generator then will produce the same exact pattern of data when reset with the initial seed value. Using this method, both the random addresses and random data produced during the writing phase can be sequenced again for the reading phase in order to check for data corruption. This method requires no additional overhead for keeping track of the sequence of random number values written to the address range.

Considering an example of a memory 0x0 to 0x64, to produce the desired memory range, the mask, and subsequently, the desired memory range, may be determined as follows:

Memory range from 0x0-0x64
0x0 (start)
0x8
0x16
0x24
0x32
0x40
0x48
0x56
0x64 (end)
Note that in the above definition, the last address of a memory rage is not inclusive.

The mask is then determined by:

Mask=(random_number % ((end−start)/8))*((end−start)/8).

### EXAMPLE 1

random_number=59863

Mask=(59863% 8)*8

Mask=(7)*8

Mask=56−>0x56=random_address

### EXAMPLE 2

random_number=51

Mask=(51% 8)*8

Mask=(3)*8

Mask=24−>0x24=random_address

No matter what random number is given to the mask operation, the above process always will result in a random address location that falls within the specified range (e.g., here 0x0 to 0x64). That is because any random number that has the modulo operation performed on it with a secondary number will always return a value less than the secondary number.

The above-described, seeded random number generator then is used to provide both random addresses and random data to write to memory locations. However, his technique could lead to situations (thrashing) where a random address may be accessed more than once. In order to eliminate thrashing, the address pointed to by the base address pointer, which is the first address in the memory range that has not been written to (i.e. has only been initialized to 0), is used as a default memory location if a randomly accessed memory location has a non-zero value (i.e. has already been written to).

Each memory element in the memory queue is written to in this manner separately. The randadref algorithm then sleeps for a specified amount of time. The random number generator then is reseeded for a memory range in the memory queue and the random number generator returns the same exact sequence of random numbers. With the same sequence of random numbers, random data values that were written to memory can now be read back and compared with what was written, and in the same order in which the random data values were written to memory. The randadref algorithm keeps track of what was written to, or read from, each memory location because once a particular memory location is read and its actual value compared with the expected value, the randadref algorithm writes all 1's to that memory location. Thus, if the randadref algorithm accesses a memory location that already has been read, the randadref algorithm again will default to the base address pointer.

With this design the randadref algorithm is able to keep track of both the random addresses that have been written to or read from, and the exact order in which those memory locations were accessed. Furthermore, the randadref algorithm is able to keep track of the exact data that are written to or read from those random addresses.

Between the reads and writes, the randadref algorithm will idle for a predetermined amount of time, which, for example, may be three seconds. This design allows memory DIMMs to be refreshed numerous times in order to validate the DIMM's refresh logic. As mentioned before, the memory range allocated to be tested may be as nominal as a single page of memory. If for example, 20 pages of memory are to be tested, but a kernel allocates the memory pages in chunks of one page, three pages, five pages, four pages, one page, two pages, and four pages, the idle time would essentially be the product of three seconds multiplied by the total number of chunks. In the above example, a total idle time of 21 seconds would result. Because there usually is more than 20 pages of memory to test and because the memory is subsequently more fragmented, the total idle time could substantially increase the randadref algorithm's run time.

To remedy this side affect, the memory ranges, or chunks, to be tested can be queued up and stored in an array. For our example, all writes will occur for the queued memory chunks consisting of the 20 pages. The randadref algorithm will then idle only once for a predetermined time followed by reading the values back to validate that no data corruption occurred. This method substantially decreases (by a factor of the size of the memory queue) the total idle time the randadref algorithm utilizes to refresh DIMMs.

When memory ranges are stored in the array, or queue, each such memory range may use a unique version of the randadref algorithm; that is, each memory range may use a differently seeded random number generator. Alternatively, the same random number generator may be used for all memory ranges in the memory queue.

The randadref algorithm's input is the memory queue of size n and an initial seed value. The randadref algorithm returns zero on successful completion. If during testing, a software mismatch is encountered, where a value read back does not match what was written to a specific memory location (i.e. data corruption), the randadref algorithm returns the address of the software mismatch as well as the actual and expected values.

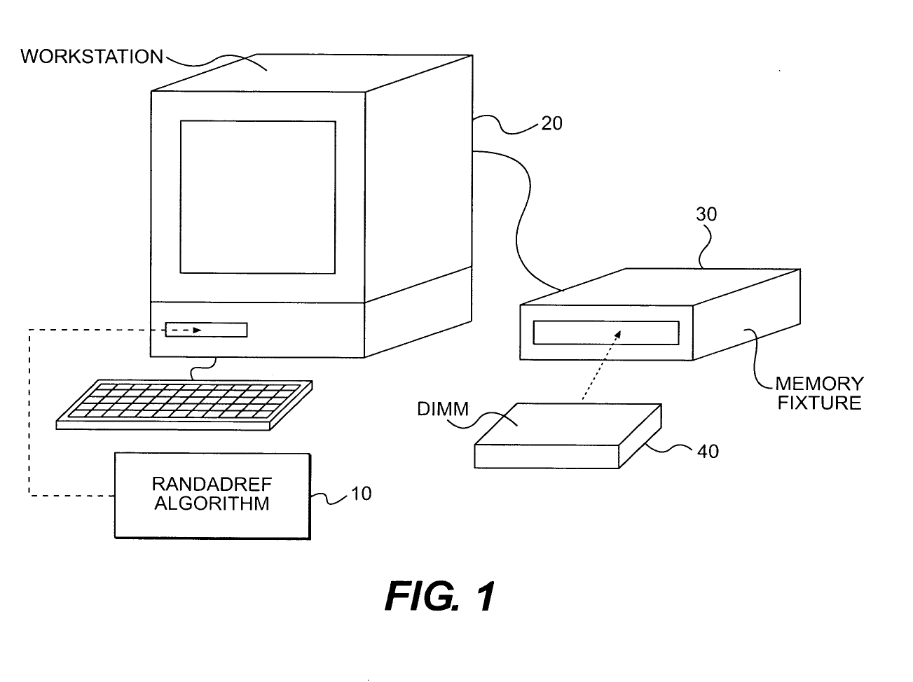

FIG. 1 illustrates an exemplary system for post-production testing of memory modules including, for example, DIMM. In FIG. 1, a workstation 20 connects to memory fixture 30. Memory fixture 30 is used to house a memory module, such as DIMM 40, during testing. The workstation 20 may be programmed to run any number of tests on the DIMM 40. In an embodiment, the workstation 20 is programmed with randadref algorithm 10. The randadref algorithm 10 may be stored on a computer readable medium (not shown), such as an optical disc.

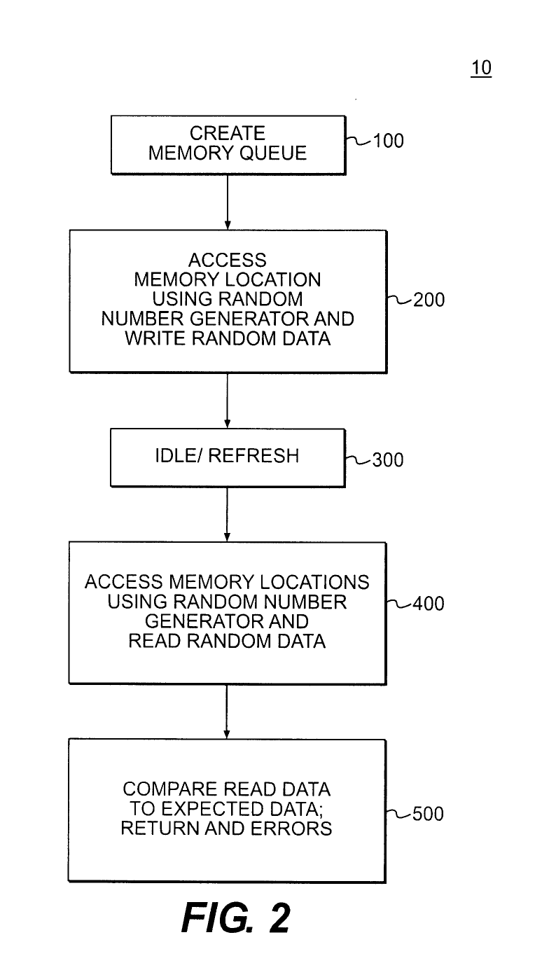

FIGS. 2-4(b) are flowcharts illustrating exemplary operations of an embodiment of the randadref algorithm 10, such as the randadref algorithm 10. The flowcharts illustrate specific routines and steps to accomplish post-production testing of memory devices. However, the routines and steps are exemplary, and not all steps are required in all embodiments of the randadref algorithm 10, and not all steps need be performed in the order illustrated.

In FIG. 2, the randadref algorithm 10 operation begins, block 100, with creation of a memory queue. In block 200, an exemplary memory accessing and data writing routine of the randadref algorithm 10 operates to access memory locations within memory space M, using a random number generator, and then writes random data to each of these memory locations. Next, in block 300, the randadref algorithm 10 provides a refresh operation by idling the operation for a specified time. In block 400, an exemplary memory accessing and reading routine of the randadref algorithm 10, using the random number generator of block 200, operates to access the memory locations, and read the random data contained therein. If the random data read from a memory location does not match the expected value, the randadref algorithm 10 returns an error condition.

Finally, in block 500, an exemplary comparison routine of the randadref algorithm 10 operates to compare the random data read from the memory locations to expected values of the random data. Should random data read from a memory location not match the expected value, the randadref algorithm 10 returns an indication of an error condition.

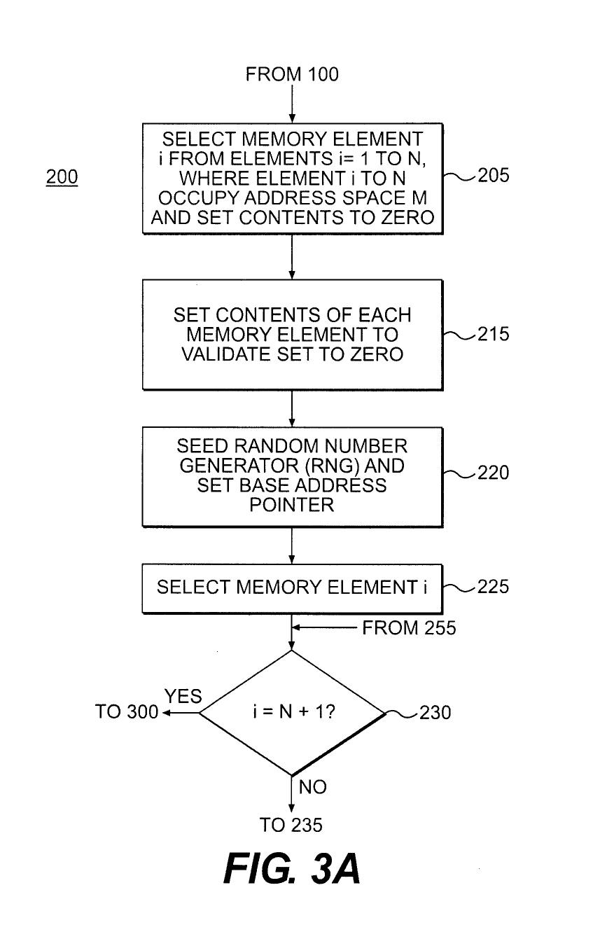

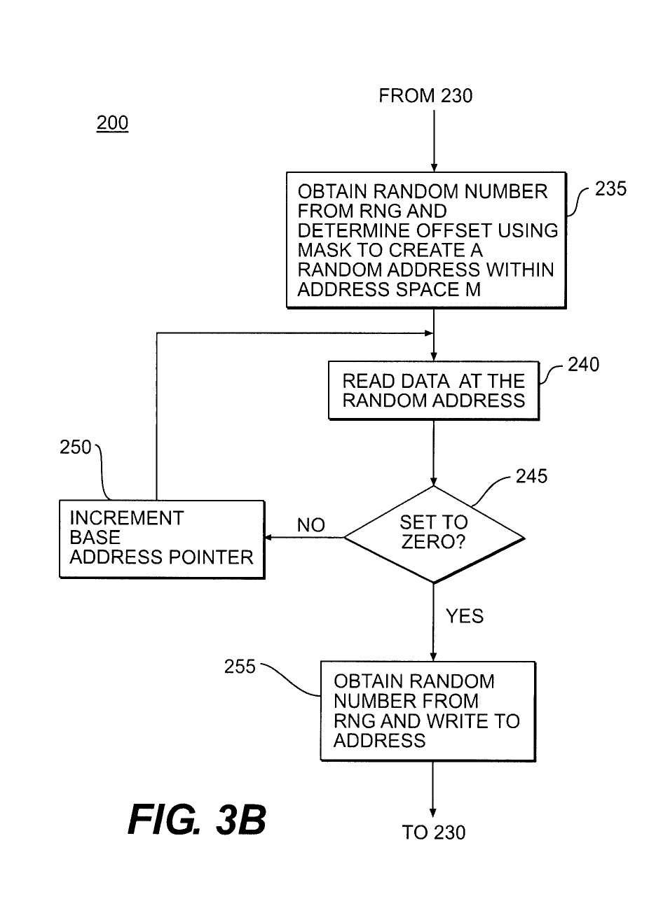

FIGS. 3(a) and 3(b) are more detailed flowcharts illustrating an embodiment of memory accessing and data writing routine of block 200. In block 205, starting at the start address of the memory address space M (containing memory elements i to N) and continuing to the end address of the memory address space M, the contents (data) of each memory element is set to zero. In block 215, the contents of each memory element in the memory address space M is read back to validate the zero condition. When all memory elements i have been set to zero, the routine of block 200 proceeds to block 220, where the random number generator is seeded with an initial value and the base address pointer is set to the start of the memory address space M. In block 225, the i^{th} memory element is selected, and in block 230, is tested to ensure that the memory element has not already been selected.

In block 235, a random number is obtained from the random number generator, and, if not already done, an offset is determined using a mask, so as to create a random address within the address space M. In block 240, data at the random address is read, and in block 245, the data read are checked to ensure the data are all zeros. If the data are not all zeros (meaning the address space has already been written to), the process move to block 250 and defaults back to the base address pointer, which has been incremented to the next memory space having all zeros for data. The process then returns to block 240. If, in block 245, the data are all set to zero, the process moves to block 255, where a random number is obtained from the random number generator, and the obtained random number is used to write random data to the memory address space. The process then repeats with the random number generator being used to select the next random address, and with the base address pointer incrementing to the next memory address space having all zeros. The processes of block 200 thus ensure that all of the memory addresses within the memory address space M are written to with random data.

Following the operation of block 200, the randadref algorithm 10 executes refresh routine 300 by idling the test operation for a specified time, as noted above.

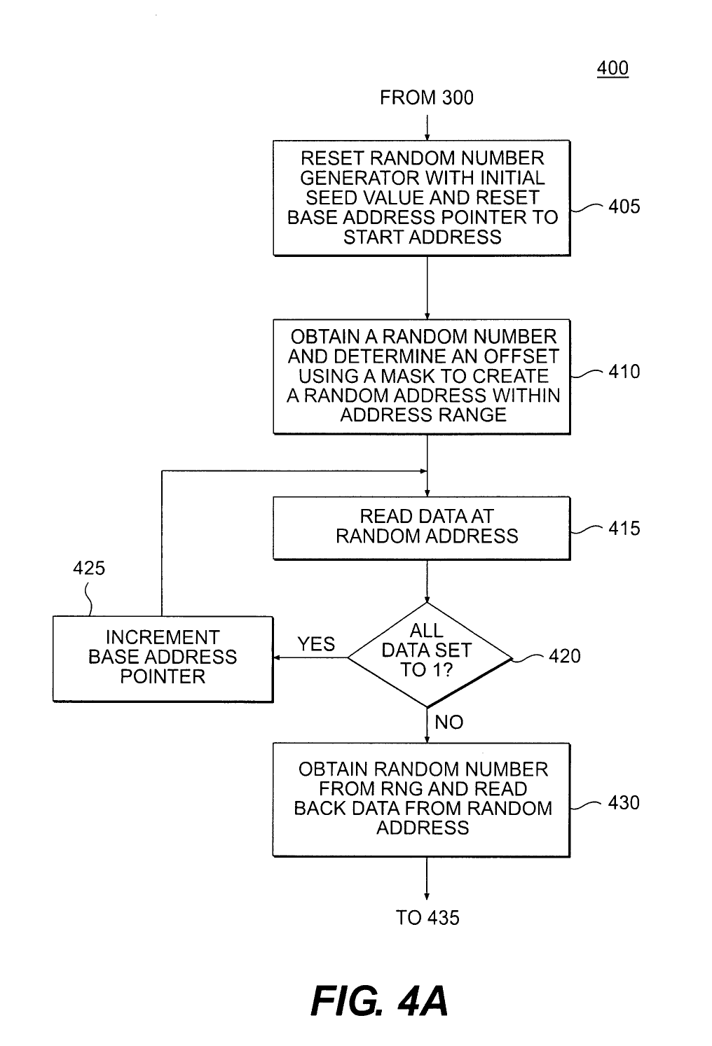

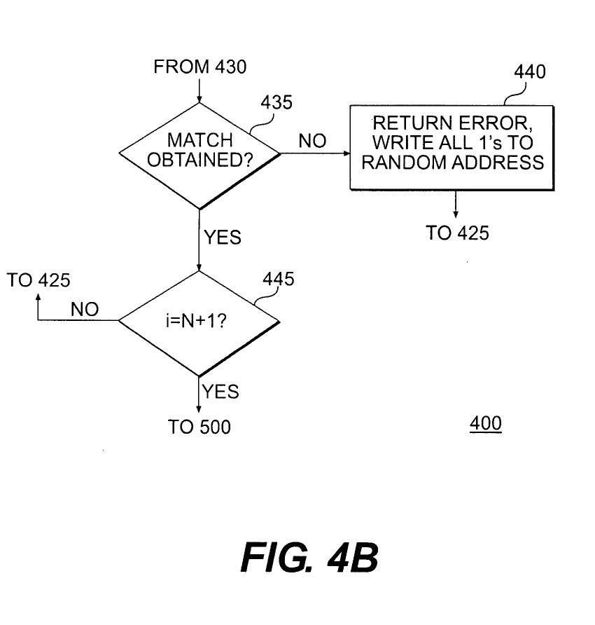

Following operations according to block 300, the randadref algorithm 10 provides for random data access, reading, comparison and error checking routine 400, embodiments of which are shown in more detail in FIGS. 4(a) and 4(b). In block 405, the random number generator is reset with the initial seed value used in block 220, and the base address pointer is reset to the start address of the memory space M. In block 410, the random number generator is used to obtain a random number, and an offset is calculated using a mask, thereby creating a random address within the address space M. Because the random number generator as used during the routine 400 is seeded with the same value as used during the routine 300, the random address generator accesses and reads data from memory address spaces in the same order as was used for writing data. In block 415, data at the random address are read, and in block 420, the read data are checked to verify all data are not all set to 1. If the data at the address is not set to all ones, the process obtains a random number using the random number generator and verifies that the value matches with what is read back from the memory address space. If the values do not match, then the randadref algorithm 10 returns an error and writes all ones to the memory address location. If the data are all set to 1, the process moves to block 425, and defaults back to the base address pointer, which has been incremented until a memory address space with the values not all set to 1 has been located. That is, the steps 415, 420, and 425 are repeated until a random address is produced wherein not all the data are set to 1. When this condition is obtained, the process moves to block 430, where a random number is obtained from the random number generator and data from the random address are read. In block 435, the operation determines whether the random number obtained in the operation of block 430 matches the data read from the random address. If the data do not match, the process moves to block 440 and the randadref algorithm 10 returns an error condition, including the values of the data read from the random address as well as the expected value of the random data. The process then returns to block 425. In block 435, if the data match, the process moves to block 445, and the operation determines if the random address corresponds to the last memory element to be read. If no more memory elements are to be read, the operation moves to block 500. Otherwise, the operation returns to block 425.

As noted above with respect to FIG. 2, during execution of routine 500, after all the memory elements have been read back, the randadref algorithm 10 reads the address of each memory element I to N in the memory address space M to verify that the data set for the memory elements is all 1's. Should random data read from a memory location not match the expected value, the randadref algorithm 10 returns an indication of an error condition. This step also ensures that the randadref algorithm 10 has accessed each memory element.

The randadref algorithm 10 combines three powerful memory test algorithms into one hybrid memory test algorithm. The test coverage benefits of random address accessing and random data values are incorporated with DIMM refresh testing. This randadref algorithm 10 better simulates real life conditions that each individual algorithm is unable to simulate. At the same time, the randadref algorithm 10 is designed to minimize the limitations and bottlenecks for each of the three algorithms.

Using both a base address pointer and seeding a pseudo random number generator the time needed to randomly access and write random data to memory is significantly decreased. There is no excessive trashing caused by accessing address locations that have already been accessed while skipping over untouched addresses within a memory range. Moreover, writing random data to these random addresses further helps to create real world scenarios that sequential memory testing with static sets of patterns simply fail to provide. The refresh portion of the randadref algorithm 10, which tests a DIMM's ability to retain data over a period of time, can be time consuming, particularly for a fragmented memory. By queuing up series of writes and reads in between idling, the effectiveness of a refresh test can be exploited by minimizing its impact on overall test time.

1. A method for testing a computer memory, comprising
creating a memory queue, wherein memory elements to be tested are stored;
initializing the computer memory comprising:
for each memory element in the computer memory, write all zeros to the memory element, and
for each memory element, verify the memory is set to all zeros by reading back data from the data element;
seeding a random number generator and setting a base address pointer to establish a start address in the computer memory;
using the seeded random generator, generate a first random number that corresponds to a first random address in the computer memory;
at the first random address, and using the random number generator to create a second random number that corresponds to a random data value, writing the random data value to the first random address;
incrementing the base address pointer to a memory element having all zeros, using the random number generator, generating a second random address, and repeating the step of creating a random data value and writing the created random data value until all elements in the computer memory have random data written thereto;
initiating a refresh test of the computer memory; and
following the refresh test, reading the random data values from each of the data elements.

2. The method of claim 1, wherein generating a first random number comprises using a mask to generate an address within a memory range comprising the computer memory.

3. The method of claim 1, wherein initiating the refresh test comprises idling the test for a predetermined time during which the computer memory is refreshed.

4. The method of claim 1, wherein writing the random data values comprises writing the random data values in a specific address order and according to a specific data pattern and wherein reading the random data values comprises:
resetting the random number generator with the initial seed value;
resetting the base address pointer to the start address in the computer memory;
using the mask to create a random address within the computer memory;
at the random address, determining if all read random data are set to ones;
if the read random are not all ones, reading the random data;
if the read random data are all ones, defaulting to the base address pointer, wherein reading the random data comprises reading the random data values in the same address order and according to the same data pattern used for writing the random data; and
incrementing the base address pointer to a subsequent address having not all ones for data.

5. The method of claim 1, further comprising:
comparing the random data values read from the memory elements to expected values for the random data elements; and
if the values do not match, declaring an error.

6. The method of claim 5, further comprising, in the event of a declared error, returning the read random data values and the expected data values.

7. The method of claim 1, wherein when the memory element to be written to contains non-zero data, the method further comprises defaulting to the base address pointer.

8. A method for testing a memory range of a Dual Inline Memory Module (DIMM), wherein the memory range comprises a plurality of memory elements, the method, comprising
(a) initializing each memory element to zero;
(b) using a seeded random number generator, determining a random address in the memory range;
(c) using the seeded random number generator, writing a random data value to the random address;
(d) repeating steps (b) and (c) until all memory elements have been written to with random data values;
(e) conducting a refresh test of the memory range; and
(f) using the same seeded random number generator, reading each of the memory elements in the memory range.

9. The method of claim 8, wherein conducting the refresh test, comprises idling the test for a predetermined time during which the DIMM is refreshed.

10. The method of claim 8, wherein generating the random address comprises using a mask to generate an address within a memory range comprising the DIMM.

11. The method of claim 8, wherein writing the random data values comprises writing the random data values in a specific address order and according to a specific data pattern and wherein reading the random data values comprises reading the random data values in the same address order and according to the same data pattern.

12. The method of claim 8, further comprising:
comparing the random data values read from the memory elements to expected values for the random data elements; and
if the values do not match, declaring an error.

13. The method of claim 12, further comprising, in the event of a declared error, returning the read random data values and the expected data values.

14. The method of claim 8, further comprising:
when writing to the memory elements in step (b), the method further comprises:
setting a base address pointer to an address in the memory range,
incrementing the base address pointer to a subsequent address having all zeros for data,
if the data at the address determined in step (b) reads all zeros, calling the random number generator to write data to the address, and
if the data at the address determined in step (b) are non zero, defaulting to the base address pointer, wherein the base address pointer increments to a subsequent address having all zeros for data; and
when reading from the memory elements in step (f), the method further comprises:
setting a base address pointer to an address in the memory range,
incrementing the base address pointer to a subsequent address having not all ones for data,
if the data at the address determined in step (f) reads not all ones, reading data from the address, and
if the data at the address determined in step (f) reads all ones, defaulting to the base address pointer, wherein the base address pointer is incremented to a subsequent address having not all ones for data.

15. A device for testing a computer memory, the computer memory comprising a plurality of memory elements, the device comprising a computer-readable medium on to which is encoded a hybrid test algorithm for testing the computer memory, the algorithm, when executed, comprising the steps of:
(a) creating a memory queue, wherein memory elements to be tested are stored;
(b) initializing each memory element to zero;
(c) using a seeded random number generator, determining a random address that corresponds to a start point in the memory range;
(d) using the seeded random number generator, writing a random data value to the random address;
(e) repeating steps (c) and (d) until all memory elements have been written to with random data values;
(f) conducting a refresh test of the memory range; and
(g) using the same seeded random number generator and the same written random data values, reading each of the memory elements in the memory range.

16. The device of claim 15, wherein conducting the refresh test, comprises idling the test for a predetermined time during which the computer memory is refreshed.

17. The device of claim 15, wherein generating the random address comprises using a mask to generate an address within a memory range comprising the computer memory.

18. The device of claim 15, wherein writing the random data values comprises writing the random data values in a specific address order and according to a specific data pattern and wherein reading the random data values comprises reading the random data values in the same address order and according to the same data pattern.

19. The device of claim 15, the steps further comprising:
comparing the random data values read from the memory elements to expected values for the random data elements; and
if the values do not match, declaring an error.

20. The device of claim 19, the steps further comprising, in the event of a declared error, returning the read random data values and the expected data values.

21. The device of claim 15, the steps further comprising:
when writing to the memory elements in step (b), further comprising:
setting a base address pointer to an address in the memory range,
incrementing the base address pointer to a subsequent address having all zeros for data,
if the data at the address determined in step (b) reads all zeros, calling the random number generator to write data to the address, and
if the data at the address determined in step (b) are non zero, defaulting to the base address pointer, wherein the base address pointer increments to a subsequent address having all zeros for data; and
when reading from the memory elements in step (f), further comprising:
setting a base address pointer to an address in the memory range,
incrementing the base address pointer to a subsequent address having not all ones for data,
if the data at the address determined in step (f) reads not all ones, reading data from the address, and
if the data at the address determined in step (f) reads all ones, defaulting to the base address pointer, wherein the base address pointer is incremented to a subsequent address having not all ones for data.

22. The device of claim 15, wherein the memory elements are arranged in groups of memory elements, and wherein a plurality of differently seeded random number generators operate on the groups of memory elements.
